(19) United States
(12) Patent Application Publication
(10) Pub. No.: US 2006/0134535 A1
(43) Pub. Date: Jun. 22, 2006

(54) Lensed fiber array for sub-micron optical lithography patterning

(75) Inventor: Jerome C. Porque, Austin, TX (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/020,864

(22) Filed: Dec. 22, 2004

(51) Int. Cl. G03B 27/00; G03F 9/00; G03C 5/00

(52) U.S. Cl. 430/30; 355/18; 430/22

(57) ABSTRACT

In accordance with various embodiments, there is an exposure system for writing a pattern on a photosensitive material. The exposure system can include a waveguide array and a light modulator. The waveguide array can include a plurality of optical fibers that focuses light on the radiation sensitive material. The light modulator can modulate the light coupled into the plurality of optical fibers. Exemplary exposure systems can reduce aberrations due to coma and distortion, and provide improved alignment.

### FIELD OF THE INVENTION

The invention generally relates to methods for image writing and exposure systems for image writing and, more particularly to methods and apparatus for maskless lithography.

### BACKGROUND OF THE INVENTION

As the minimum feature size of integrated circuits continues to shrink and the complexity of the patterns continues to grow, the cost of fabrication, inspection, and handling of masks for use in conventional exposure systems continues to rise. Conventional exposure systems, such as, for example, optical lithography systems, use optical steppers to image a reticle or “mask” through a lens to create a pattern on a layer. The area to be patterned on the layer is generally much larger than the field size of the imaging lens, so multiple exposures must be made using a step-and-repeat system. Alternatively, the layer can be patterned by moving the reticle and the layer at the same time in opposite directions using a step-and-scan system.

Conventional exposure systems must also achieve high resolution and low distortion imaging. To increase the resolution, optical lithography systems, for example, use high numerical aperture (NA) imaging systems consisting of multi-element optics. The high tolerance requirement for the optics presents manufacturing difficulties and the precise alignment requirement for the multiple elements presents operational difficulties. Problems also arise because the multi-element optics must provide dimensional stability over large distances between optical and mechanical components to maintain resolution, focus, and accuracy.

U.S. Pat. No. 6,133,986 discloses a conventional maskless lithography system that uses a low NA imaging system coupled with an array of high NA micro-lenses. The disclosed system consists of a spatial light modulator, multiple collimating lenses, an aperture array, and a micro-lens array. In the disclosed system, collimated light from the spatial light modulator is imaged onto the aperture array. The microlens array collects the light from the aperture array and focuses it onto the surface to be patterned. As the feature size decreases, however, system alignment of the conventional maskless lithography system becomes more difficult and problems arise due to aberrations, such as, spherical aberration, coma, and distortion.

Thus, there is a need to overcome these and other problems of the prior art and to provide better methods for image writing and improved apparatus for maskless image writing.

### SUMMARY OF THE INVENTION

In accordance with various embodiments, there is an exposure system including a waveguide array that guides light to pattern a radiation sensitive material. The waveguide array can include a plurality of waveguides. The exposure system can further include a light modulator to independently modulate light coupled into the plurality of waveguides of the waveguide array.

In accordance with various embodiments, there is also a lithography system including a light source that provides an ultraviolet (UV) light, an optical element that modulates the UV light, and a fiber array comprising a plurality of optical fibers to focus the modulated UV light. The exposure system can further include a stage disposed to move a substrate relative to the fiber array.

In accordance with various embodiments, there is also a method for lithography. A modulated light can be coupled into a plurality of optical fibers. The modulated light can be focused onto a photosensitive material disposed on a substrate using the plurality of optical fibers. A desired pattern can then be written in the photosensitive material by at least one of translating and rotating the substrate relative to the plurality of optical fibers.

It is to be understood that both the foregoing general description and the following detailed description are exemplary and explanatory only and are not restrictive of the invention, as claimed.

The accompanying drawings, which are incorporated in and constitute a part of this specification, illustrate several embodiments and together with the description, serve to explain the principles of the invention.

### BRIEF DESCRIPTION OF THE DRAWINGS

FIG. 1 depicts a schematic view of an exposure system for image writing in accordance with exemplary embodiments of the present teachings.

FIGS. 2A and 2B depict schematic views of an optical fiber including a lensed tip in accordance with exemplary embodiments of the present teachings.

FIGS. 3A and 3B depict end views of waveguide placement in waveguide arrays in accordance with exemplary embodiments of the present teachings.

FIG. 4 depicts a schematic view of a fiber alignment system in accordance with exemplary embodiments of the present teachings.

FIGS. 5A-5D depict schematic views of waveguide arrays rotated to minimize errors and change pitch.

FIG. 6 depicts a schematic view of an exposure system for image writing in accordance with exemplary embodiments of the present teachings.

FIG. 7 depicts a perspective view of a waveguide array including lensed tips in accordance with exemplary embodiments of the present teachings.

FIG. 8 depicts a cross sectional view of a waveguide array including lensed tips including optical fibers in accordance with exemplary embodiments of the present teachings.

FIG. 9 depicts a partial cross sectional view of a waveguide array a and plurality of VCSELs integrated on a substrate.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

As used herein, the term “pitch” refers to a center-to-center distance between two lines written in a radiation sensitive material by adjacent waveguides, such as, for example, optical fibers.

As used herein, the terms “detector” and “optical detector” refer to any component or system of components that can detect light including, for example, a charged coupled device (CCD), a photodiode or a photodiode array, a complimentary metal-oxide semiconductor (CMOS) sensor, a CMOS array, and a photomultiplier tube (PMT).

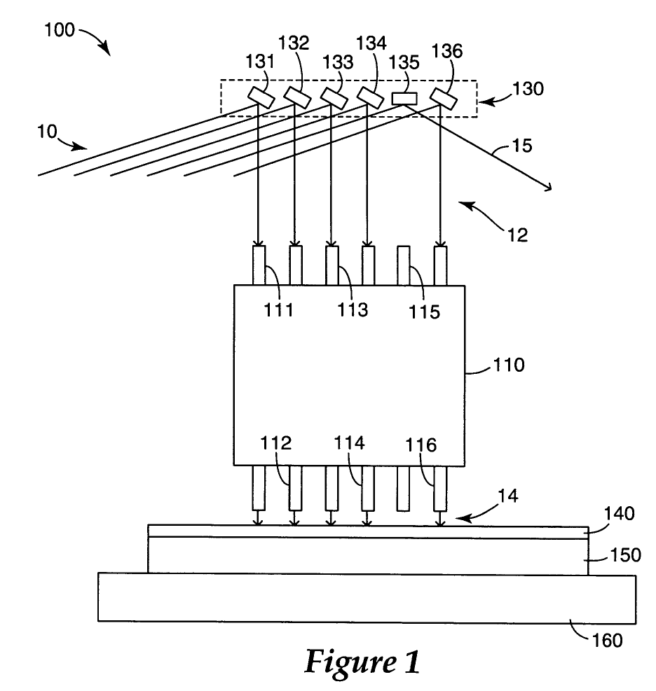

FIGS. 1-9 disclose exposure systems for image writing in accordance with exemplary embodiments of the present teachings. The exemplary exposure systems include a modulator to modulate light and a waveguide array including a plurality of waveguides. The plurality of waveguides can guide and focus the modulated light onto a photosensitive layer, thereby reducing aberrations due to coma and distortion. The exemplary exposure systems also provide improved alignment, as they are more stable, compact, and easier to maintain than conventional maskless lithography systems.

FIG. 1 depicts a schematic view of an exemplary exposure system 100 for image writing including a waveguide array 110 and a light modulator 130. According to various embodiments, waveguide array 110 can be a fiber array comprising a plurality of optical fibers 111-116. Plurality of optical fibers 111-116 can be optimized to transmit light, represented by arrows 10, from a light source (not shown) for writing a pattern in a radiation sensitive material, such as, for example, a photosensitive material. Light 10 can be, for example, ultraviolet (UV) light, visible light, or infrared light. In various embodiments, plurality of optical fibers 111-116 can be single mode optical fibers optimized to transmit light of about 405 nm. Examples of such optical fibers include 405-HP and S405 made by Nufern (East Granby, Conn.). One of ordinary skill in the art understands that the number of optical fibers shown in fiber array 110 is exemplary and that the number of optical fibers in a fiber array can be selected as desired.

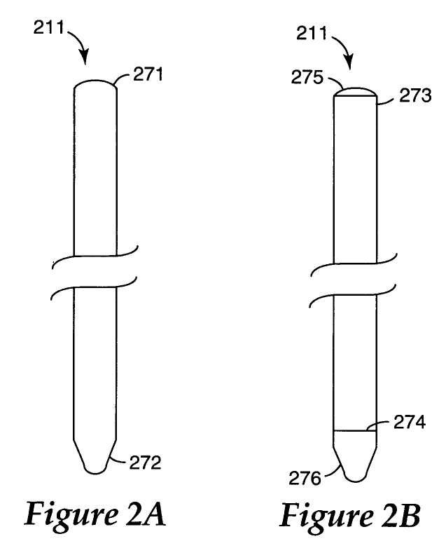

In various embodiments, one or both ends of optical fibers 111-116 can include a flat, a convex, or a concave shape. Optical fibers 111-116 can have a light input end that, for example, facilitates coupling and propagation of light entering the fiber. Referring to FIG. 2A, a schematic view of an optical fiber 211 is shown. Optical fiber 211 can have a light input end 271 with, for example, a convex shape that facilitates coupling and propagation of light entering the fiber. In various embodiments, light input end 271 can have a low NA. The shape of input end 271 can be formed by methods known to one of skill in the art, such as, for example, milling, grinding, and polishing.

Optical fibers 111-116 can further have a light output end that, for example, facilitates focusing of light exiting the optical fiber. Referring to FIG. 2A, optical fiber 211 can have a light output end 272 with a lensed tip. The lensed tip can be a convex shape that focuses light exiting the optical fiber. The convex shape can be, for example, a cylindrical lens shape, a spherical lens shape, or an aspherical lens shape formed on the output end of optical fiber 211. In various embodiments, light output end 272 can have a high NA to focus the light. The shape of output end 272 can be formed by methods known to one of skill in the art, such as, for example, milling, grinding, and polishing.

In various embodiments, one or both ends of optical fibers 111-116 can include a lens. Referring to FIG. 2B, a schematic view of optical fiber 211 is shown. Optical fiber 211 can have a light input end 273 having a flat shape. Light input end can further include a lens 275 that facilitates coupling and propagation of light entering optical fiber 211. Lens 275 can be, for example, a plano-convex lens coupled to optical fiber input end 273 by a conventional lens coupling method. FIG. 2B further shows light output end 274 having, for example, a flat shape. Light output end 274 can further include a lens 276 that focuses light exiting optical fiber 211. In various embodiments, lens 276 can be a spherical lens, an aspherical lens, or a cylindrical lens. Lens 276 can be coupled to light output end 274 by methods known to one of ordinary skill in the art, such as, for example, an index matching fluid and/or adhesive.

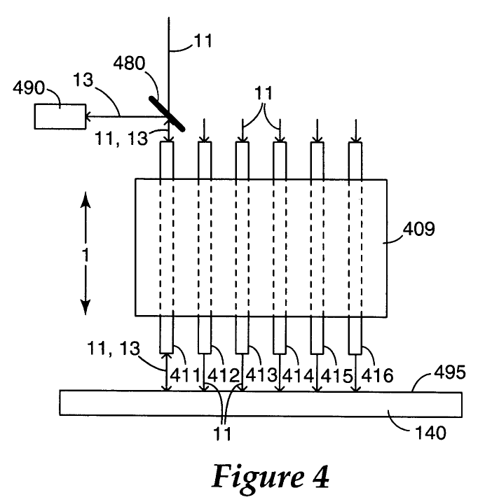

In various embodiments, the optical fibers can be mounted in a housing to form the fiber array. In various embodiments, the housing can be, for example, silicon, metals, such as, aluminum or stainless steel, and plastics, such as, moldable engineering plastics or particle reinforced plastics. FIG. 4 shows a schematic view of a housing 409 including a plurality of grooves in which a plurality of optical fibers 411-416 can be placed. The grooves (not shown) can be formed in housing 409 by, for example, etching, machining, or molding. Each of the plurality of optical fibers 411-416 can then be independently adjusted in the groove along an axis 1 for optimal alignment. Optical fibers 411-466 can be mounted in the grooves by methods known to one of ordinary skill in the art, such as, for example, adhesive bonding or glass solders. If an array of fibers is desired containing two or more rows of fibers, multiple grooved plates may be stacked up to form housing 409. As shown in FIG. 4, a light 11, which in various embodiments has passed through light modulator 130, can pass through a beam splitter 480 and be coupled into optical fiber 411. In various embodiments, the wavelength of light 11 can be the same as the wavelength of light 10 used to pattern the resist. In various other embodiments, the wavelength of light 11 can be chosen to enhance reflection from surface 495. A light 11 can then exit optical fiber 411 and reflect from surface 495 of resist layer 140. A reflected light 13 from surface 495 can be coupled back into optical fiber 411, exit optical fiber 411, and reflect from beam splitter 480 to a detector 490. By measuring the amplitude of the signal, the focal point of the light output end of the optical fibers or the lens coupled to the output end of the optical fibers can be determined. In this manner, each optical fiber 411-416 can be independently adjusted along axis 1 to correct variations in the focal length of the optical fiber ends and/or the lenses.

In various embodiments, optical fibers 111-116 can be mounted in a plurality of housings. Each of the plurality of housings can include fibers oriented in, for example, a row. A single housing or a plurality of housings bundled together can be used to write a pattern in the photosensitive material. For example, more housings can be bundled together for writing a larger pattern and fewer housing can be bundled together for writing a smaller pattern. Moreover, the orientation of the housings with respect to each other can be arranged to change the pitch.

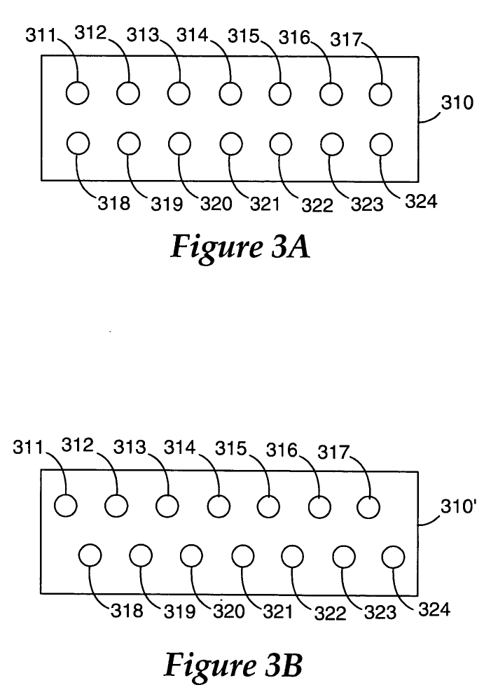

The optical fibers can be arranged in the housing in a linear manner, as plurality of optical fibers 111-116 are in fiber array 110 shown in FIG. 1. In various embodiments, the optical fibers can be arranged in other orientations, such as, for example, in a plurality of rows. FIG. 3A shows, a plurality of optical fibers 311-324 arranged in two rows in fiber array 310. Optical fibers 311-317 can form a first row and optical fibers 318-324 can form a second row. The first row of optical fibers 311-317 can be positioned directly above the second row of optical fibers 318-324 symmetrically in a linearly aligned orientation.

The optical fibers can further be arranged in an interleaved orientation. FIG. 3B shows, plurality of optical fibers 311-324 arranged in two rows in fiber array 310′. Optical fibers 311-317 can form a first row and optical fibers 318-324 can form a second row. In various embodiments, first row of optical fibers 311-317 can be positioned above second row of optical fibers 318-324 such that optical fibers 311-317 in the first row are not directly above optical fibers 318-324 in the second row. In this manner, optical fibers 311-324 can be disposed in an interleaved orientation. One of ordinary skill in the art understands that the number of rows of optical fibers shown in FIGS. 3A-B and the arrangement of the optical fibers is exemplary and that additional rows and other arrangements can be used.

Referring back to FIG. 1, light modulator 130 can deliver light 12 to the optical fibers of fiber array 110. Light modulator 130 can, for example, modulate one or more of the phase, frequency, amplitude, and direction of the light. In various embodiments, light modulator 130 can be an electro-optic modulator or an acousto-optic modulator. In various other embodiments, light modulator 130 can be a micro-electro-mechanical system (MEMs) that spatial modulates light by mechanical actuation of a plurality of optical elements 131-136. Optical elements 131-136 can be, for example, mirrors. Examples of MEMS-based spatial light modulators include the Digital Micromirror Device made by Texas Instruments Inc. (Dallas, Tex.) and the Grating Light Valve made by Silicon Light Machines (Sunnyvale, Calif.). As shown by optical element 135, modulation of light can occur by tilting or phase-shifting one or more of the optical elements to reduce the intensity of light coupled into corresponding optical fiber 115 and, thus, the deflected (or reflected) light 15 is guided away from resist layer 140 which comprises a photosensitive material. In various embodiments, light modulator 130 can further include a micro-lens array (not shown) to assist coupling of light into optical fibers 111-116. The micro-lens array can be, for example, a plurality of convex lenses, a plurality of convergence waveguides, other optical elements to couple light into an optical fiber known to one of ordinary skill in the art, or any combination thereof.

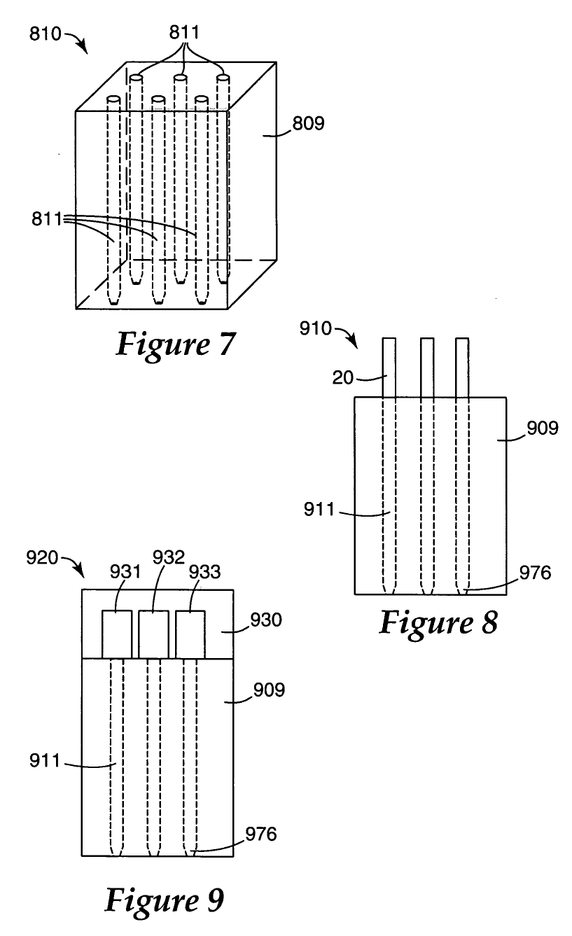

In various embodiments, waveguide array 110 shown in FIG. 1 can further be a waveguide formed in a bulk optical material by, for example, a femtosecond laser. As shown in the perspective view of FIG. 7, a waveguide array 810 can include a plurality of waveguides 811 having a lensed tip formed in bulk optical material 809. Bulk optical material 809 can be glass, such as, for example, fused and synthetic silica, Ge-doped silica, borosilicate, borate, phosphate, fluorophosphates, fluoride, and chalcogenide glasses. Plurality of waveguides 811 can be formed in bulk optical material 809 by photoinduced refractive index change with an ultrashort pulsed laser, such as a femtosecond laser. The femtosecond laser, generating energies up to about 100 nj, can locally increase the refractive index of bulk optical material 809 at the focal point. The three-dimensional waveguides can be formed, for example, by focusing the laser within bulk optical material 809 and translating bulk optical material 809 in two dimensions perpendicular to the axis of the laser beam (e.g., x-y directions) and parallel to the axis of the laser beam (e.g., z-direction) to form waveguides 811. In various embodiments, each waveguide of waveguide array 810 can include a lensed tip 976 that facilitates focusing of light exiting each of the plurality of waveguides 811. Plurality of waveguides 811 can also be arranged in other orientations, such as, for example, in a plurality of rows, similar to the fiber orientation shown in FIG. 3A, or in an interleaved orientation, similar to the fiber orientation shown in FIG. 3B.

In various other embodiments, as shown in the cross sectional view of FIG. 8, optical fibers 20 can be coupled to waveguides 911 formed in bulk optical material 909. Optical fibers 20 can be coupled to waveguides 911 using, for example, an index matching fluid containing adhesive or a conventional butt coupling technique.

In various embodiments, waveguide array 810 can be integrated onto a substrate with the light source or joined directly to an array of individual light sources. Referring to FIG. 9, an integrated waveguide array and light source array can be assembled on a same substrate. Substrate 930 can be, for example, a semiconductor substrate, such as silicon. Integrated waveguide and light source 920 can include a waveguide array comprising of a plurality of waveguides 911 formed in a bulk optical material 909. Each of the plurality of waveguides can include a lensed tip 976 that facilitates focusing of light exiting plurality of waveguides 911. A light source array can comprise a plurality of light sources 931-933, the number of light sources corresponding to the number of waveguides. Light sources 931-933 can be, for example, VCSELs, laser diodes, or light emitting diodes (LEDs). According to various embodiments, as shown in FIG. 9, the light source array comprising VCSELs 931-933 can be integrated onto substrate 930 adjacent to the waveguide array comprising the plurality of waveguides 911 formed in a bulk optical material 909.

Operation of exposure system 100 will now be described with reference to an exemplary maskless lithography system for patterning a photosensitive layer in a semiconductor device. Referring again to FIG. 1, light 10, such as UV light, from a light source (not shown) can be directed to light modulator 130. Optical elements 131-136 of light modulator 130 can be individually controlled to modulate an amount of UV light 12 that is coupled into optical fibers 111-116 of fiber array 110. Optical fibers 111-116 can then propagate modulated UV light 12 down the length of the fibers by total internal reflection. Light 12 can exit the output ends of optical fibers 111-116 and can be incident on a resist layer 140 comprising a photosensitive material. In various embodiments, resist layer 140 can be disposed on a layer 150, such as, for example, a substrate or wafer, such as a silica-based material or glass, a metal, or a plastic material. The UV light that exits the optical fibers can be focused by the shaped output end of the optical fibers or the lens coupled to the output end of the optical fibers. In various embodiments, resist layer 140 can be positioned at the focal point of the focused UV light exiting optical fibers 111-116. Although operation of the exemplary maskless lithography system is described with respect to a fiber array, one of ordinary skill in the art understands that other waveguide arrays, as described herein, can be used.

In various embodiments, exposure system 100 can further include a stage for moving one or both of fiber array 110 and resist layer 140. The stage, for example, can move one or both of fiber array 110 and resist layer 140 in a translational and/or a rotational manner. FIG. 1 shows resist layer 140 and substrate 150 mounted on a stage 160. Stage 160 can move resist layer 140 and substrate 150 relative to fiber array 110. In various embodiments, stage 160 can translate substrate 150 to pattern resist layer 140 in a step-and-repeat manner. In various other embodiments, stage 160 can move substrate 150 and a second stage (not shown) can translate fiber array 110 to pattern resist 140 in a step-and-scan manner.

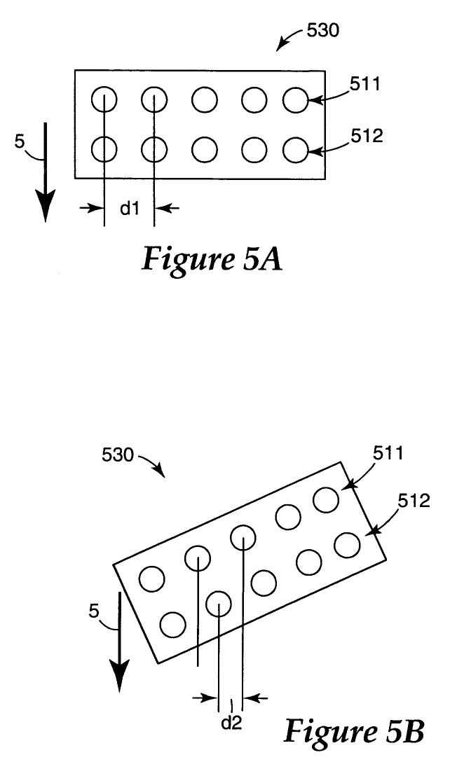

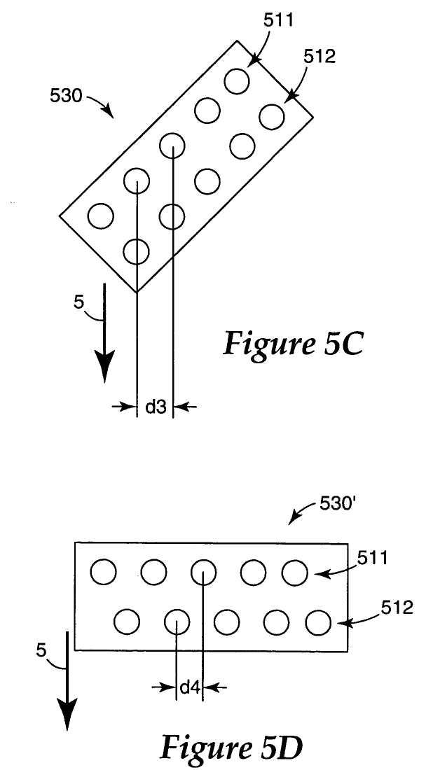

In various embodiments, exposure system 100 further includes a stage for rotating one or both of fiber array 110 and substrate 150. One of skill in the art will understand that the term “stage” includes all apparatus for translating and/or rotating substrate 150, such as, for example, a linear stage, a roll, a drum, and all combinations thereof. Fiber array can be oriented with respect to the direction of translation so that more than one optical fiber writes to the same area on the resist layer to reduce errors. Referring to FIG. 5A, a fiber array 530 can include a plurality of optical fibers arranged in a first row 511 and a second row 512. First row of optical fibers 511 and second row of optical fibers 512 can be oriented with respect to a direction of translation 5 such that the optical fibers of first row 511 write to the same area of the resist layer as corresponding optical fibers in second row 512. The pitch, in the orientation shown in FIG. 5A, is d1.

In various embodiments, the pitch can be controlled by rotating one or both of fiber array 110 and/or substrate 150. For example, as shown in FIG. 5B, fiber array 530 can be rotated so that first row of optical fibers 511 and second row of optical fibers 512 are oriented with respect to a direction of translation 5 such that pitch d2 is less than pitch d1. In various other embodiments, as shown in FIG. 5C, fiber array 530 and/or substrate (not shown) can be rotated such that more than one fiber writes to the same area to average errors. The pitch, in the rotated orientation depicted in FIG. 5C, can be d3, where d3 is less than d1. In still other embodiments, the pitch can additionally be controlled by the amount of interleaving. Referring to FIG. 5D, a pitch d4 can be less than d1 by interleaving the optical fibers of first row 511 and the optical fibers of second row 512.

In various embodiments, “immersion lithography” can be used to increase the resolution of the disclosed exposure systems. Immersion lithography uses a thin liquid film between an exposure system's projection lens and the substrate. The limit to NA for exposure systems using air as a medium is 1. Because the index of refraction (n) of a liquid is generally higher than that of air (n=1), the NA of the exposure system can be increased. Referring to FIG. 1, a liquid (not shown), such as, for example, water (n=1.33) can be disposed between an end of optical fibers 111-116 and resist layer 140. The liquid can have an index greater than 1, have low optical absorption at the patterning wavelength, and be compatible with the resist material. The liquid can be disposed between the ends of optical fibers 111-116 and resist layer 140, for example, by immersion of resist layer 140 and the ends of optical fibers 111-116 in water. The liquid can be also be disposed, for example, by dispensing with a nozzle and relying on surface tension to maintain the water between the ends of optical fibers 111-116 and resist layer 140.

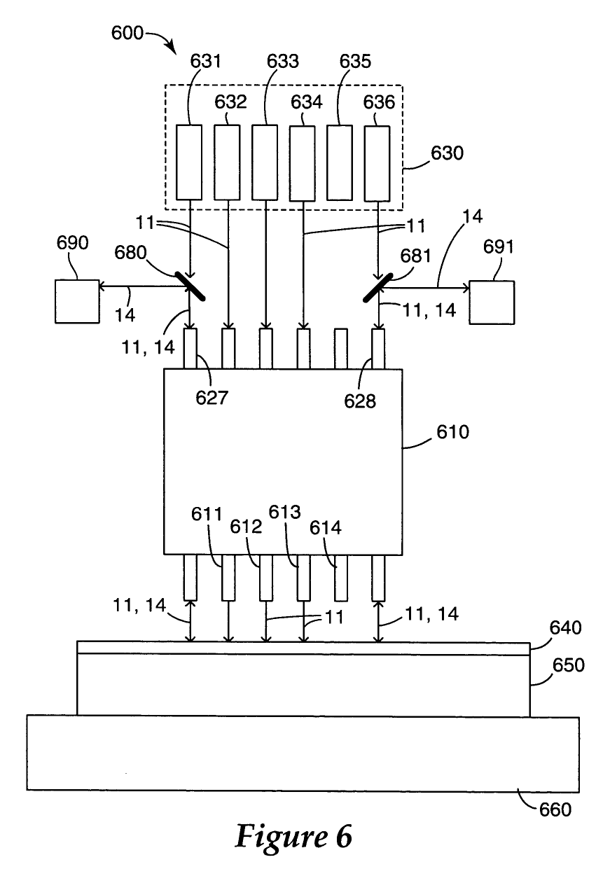

In various embodiments, the light modulator can be an array of laser diodes, such as a DBR (distributed Bragg reflector) laser diode or an array of vertical cavity surface emitting lasers (VCSELs). As shown in the schematic view of FIG. 6, an exposure system 600 can include a VCSEL array 630, which can include a plurality of VCSELS 631-636. According to various embodiments, the number of VCSELs in VCSEL array 630 can match the number of optical waveguides in waveguide array 610. VCSELS 631-636 can then be individually controlled to modulate the light coupled to corresponding optical waveguides 611-616. Thus, in this embodiment, the VCSELs serve as both the light source and light modulator. Light modulator 630 can further include a lens array (not shown) to assist coupling of light into optical waveguides 611-616.

Exemplary exposure systems can also include optical fibers and detectors to monitor the patterning and/or provide feedback on the patterning. Referring again to FIG. 6, exposure system 600 can include a light modulator, such as, for example, VCSEL array 630, and a fiber array 610 comprising a plurality of optical fibers 611-614. In various embodiments, exposure system 600 can include a first optical fiber 627 and a detector 690. A beam splitter 680 can be positioned between a light source 631 and first optical fiber 627. In operation, a light 11 from light source 63 1can pass through beam splitter 680 and couple into first optical fiber 627. Light source 631 may or may not be a VCSEL of VCSEL array 630. Light 11 can exit first optical fiber 627 and reflect from a resist layer 640. A reflected light 13 can be coupled back into first optical fiber 627. In various embodiments, the output end of first optical fiber 627 can be shaped or can include a lens to focus and/or couple the light, as discussed herein. Reflected light 13 coupled back into first optical fiber 627, can then propagate back through first optical fiber 627, exit first optical fiber 627, and reflect from a beam splitter 680. Beam splitter 680 can direct reflected light 14 to a detector 690. In various embodiments, detector 690 can measure an amplitude of the control light to track a distance between fiber array 610 and resist layer 640.

In various embodiments, detector 690 and first optical fiber 627 can be used as a microscope to monitor formation of a specific pattern in resist layer 640. Detector 690 and first optical fiber 627 can further be used as a microscope to track a position and a velocity change of fiber array 610 relative to resist layer 640.

In various embodiments, additional detectors and additional optical fibers can be used to monitor and/or control patterning of the resist layer. Exemplary exposure system 600, shown in FIG. 6, can include a second detector 691 and a second optical fiber 628. A second beam splitter 681 can be positioned between a light source 636 and second optical fiber 628. Operating similar to the first detector and first optical fiber, a control light from light source 636, that may or may not be a VCSEL of VCSEL array 630, can pass through beam splitter 681 and couple into second optical fiber 628. The control light can exit second optical fiber 628 and reflect from resist layer 640. The reflected control light can be coupled back into second optical fiber 628. As discussed above, the output end of second optical fiber 628 can be shaped or can include a lens to focus and/or couple the control light. The reflected control light coupled back into second optical fiber 628 can then propagate back through second optical fiber 628, and exit to reflect from beam splitter 681. Beam splitter 681 can direct the control light to second detector 691. In various embodiments, second detector 691 and second optical fiber 628 can monitor a distance of fiber array 610 relative to resist layer 640. In various other embodiments, detectors 690 and 691, and optical fibers 627 and 628 can monitor a longitudinal distance to follow a pattern on resist layer 640. Based on a property of the light detected by the detector, such as, for example, amplitude or phase, feedback can be provided for monitoring of exposure system 600. The number of optical fibers and detectors can vary as-desired. For example, two optical fibers can be used to define a line of detection and/or monitoring, and three optical detectors can be used to define a plane of detection and/or monitoring.

The operation of exemplary exposure system 600 will now be described with reference to a lithographic system for writing a pattern in a photosensitive material. Modulated light can be provided by VCSEL array 630 and coupled into fiber array 610. VCSELS 632-635 can be individually controlled to modulate the light as represented by VCSEL 635. By individually turning the VCSELs in the VCSEL array on and off a pattern can be written in resist layer 640. Fibers 611-614 can be used transmit the modulated light to a resist layer 640 comprising a photosensitive material. Resist layer can reside on or over a substrate 650. As known to one of ordinary skill in the art, other layers may be disposed between substrate 650 and resist layer 640. In various embodiments, substrate 650 can be disposed on a stage 660 capable of translation and/or rotation of substrate 650. In various embodiments, fiber array 610 can also be disposed on a stage (not shown) capable of translation and/or rotation of fiber array 610. Light coupled into optical fibers 611-614 can travel down a length of the optical fibers. The ends of optical fibers 611-614 can be shaped or can include lenses to focus the light exiting the optical fibers onto resist layer 640. Although operation of the exemplary exposure system is described using a fiber array, other waveguide arrays as disclosed herein can be used.

Light sources 631 and 636 can provide a control light that can be coupled into first optical fiber 627 and second optical fiber 628. The control light can travel down a length of optical fibers 627 and 628, exit optical fibers 627 and 628, and impinge on resist layer 640. The control light can be reflected from resist layer 640, coupled back into optical fibers 627 and 628, and exit optical fibers 627 and 628 at the other end. The light can then be directed to detectors 690 and 691 by beam splitters 680 and 681, respectively. In various embodiments, fiber couplers can be used to direct the light to detectors 690 and 691. Based on a property of the light detected by detectors 680 and 681, patterning of layer 640 can be monitored or adjusted as required. One of ordinary skill in the art understands that the number of components, such as, for example, optical fibers in fiber array 610, the number of VCSELS in VCSEL array 630, and the number of detectors coupled to optical fibers depicted in exposure system 600 is exemplary.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An exposure system comprising:
a waveguide array that guides light to pattern a radiation sensitive material, wherein the waveguide array comprises a plurality of waveguides; and
a light modulator to independently modulate light coupled into the plurality of waveguides of the waveguide array.

2. The exposure system of claim 1, wherein each of the plurality of waveguides comprises at least one of an optical fiber and a waveguide formed in a bulk optical material.

3. The exposure system of claim 1, wherein each of the plurality of waveguides of the waveguide array comprises:
a light input end comprising at least one of a flat, a convex, and a concave shape; and
a light output end comprising at least one of a flat and a convex shape.

4. The exposure system of claim 1, wherein each of the plurality of waveguides of the waveguide array comprises at least one of a first lens coupled to a light input end and a second lens coupled to a light output end.

5. The exposure system of claim 1, further comprising a stage to at least one of translate and rotate a substrate relative to the waveguide array, wherein the radiation sensitive material is disposed on the substrate.

6. The exposure system of claim 5, wherein the waveguide array further comprises:
at least a first waveguide; and
at least a first optical detector, where in the at least a first waveguide and the at least first optical detector track at least one of a position and a velocity change.

7. The exposure system of claim 2, wherein the waveguide array further comprises:
a plurality of waveguides; and
a plurality of optical detectors, wherein the plurality of waveguides and the plurality of optical detectors are positioned to track at least one of a relative alignment between the waveguide array and the radiation sensitive material, and patterning of the radiation sensitive material.

8. The exposure system of claim 1, wherein the waveguide array comprises a plurality of housings, and the plurality of waveguides are mounted in the plurality of housings.

9. The exposure system of claim 1, wherein the light modulator comprises:
a light source;
a spatial light modulator; and
an array of micro-lenses.

10. The exposure system of claim 1, wherein the light modulator comprises at least one of a plurality of independently modulated vertical cavity surface emitting lasers (VCSEL), a plurality of independently modulated laser diodes, and a plurality of independently modulated light emitting diodes.

11. A lithography system comprising:
a light source that provides an ultraviolet (UV) light;
an optical element that modulates the UV light;
a waveguide array comprising a plurality of waveguides to guide the modulated UV light; and
a stage disposed to move a substrate relative to the waveguide array.

12. The lithography system of claim 11, further comprising a lens disposed on at least one of an input end of each of the plurality of waveguides and an output end of each of the plurality of waveguides.

13. The lithography system of claim 11, wherein the light source and the optical element comprise a plurality of VCSELs, the waveguide array comprises a plurality of waveguides formed in a bulk material, and the plurality of VCSELs and the waveguide array are integrated on a substrate.

14. The lithography system of claim 11, further comprising:
a first optical detector;
a second optical detector;
a first beam splitting element; and
a second beam splitting element, wherein the first beam splitting element and the second beam splitting element are disposed between the optical element and the waveguide array.

15. The lithography system of claim 14, wherein the first optical detector, the second optical detector, the first beam splitting element, and the second beam splitting element monitor at least one of a distance of the optical element relative to the substrate, and a longitudinal distance to follow a pattern on a photosensitive material.

16. The lithography system of claim 11, further comprising a liquid disposed between the waveguide array and the substrate.

17. A method for lithography comprising:
coupling a modulated light into a plurality of optical fibers;
focusing the modulated light onto a photosensitive material disposed on a substrate using the plurality of optical fibers; and
writing a desired pattern in the photosensitive material by at least one of translating and rotating the substrate relative to the plurality of optical fibers.

18. The method of claim 17, further comprising orienting the plurality of optical fibers such that a feature of the desired pattern is written by more than one of the plurality of optical fibers.

19. The method of claim 17, further comprising rotating at least one of the substrate and the plurality of optical fibers to control a pitch of a written pattern.

20. The method of claim 17, further comprising adjusting a position of at least one of the plurality of optical fibers to maximize a measured signal prior to writing a desired pattern in the photosensitive material.

21. The method of claim 20, wherein adjusting the position of at least one of the plurality of optical fibers to maximize a measured signal prior to writing a desired pattern in the photosensitive material comprises:
tracking an amplitude of the light exiting from the at least one adjusted optical fiber of the plurality of optical fibers;
tracking an amplitude of the light reflecting from a surface; and
tracking an amplitude of the light coupling back into the at least one adjusted optical fiber of the plurality of fibers.

22. The method of claim 17, further comprising maintaining a relative alignment between the plurality of optical fibers and the photosensitive material by coupling a light into at least one optical fiber.

23. The method of claim 17, further comprising monitoring writing of the desired pattern in the photosentive material by coupling a light into at least one optical fiber.

24. The method of claim 17, wherein focusing the spatial modulated light onto the photosensitive material disposed on the substrate using the plurality of optical fibers comprises focusing the spatially modulated light though a lens coupled to an end of each of the plurality of optical fibers.

25. The method of claim 17, further comprising correcting an error in at least one of alignment, focus, and position during writing of the desired pattern.

26. The method of claim 17, further comprising using a liquid medium between an output end of the plurality of optical fibers and the photosensitive material.

27. The method of claim 17, further comprising correcting a non-uniformity of the light by calibrating the light coupled into each of the plurality of fibers.
